(19) United States
(12) Patent Application Publication
(10) Pub. No.: US 2009/0079891 A1
(43) Pub. Date: Mar. 26, 2009

(54) Integrated circuit, liquid crystal panel with same and method for testing integrated circuit

(75) Inventors: Li-Ya Li, Shenzhen (CN); Yi-Yin Chen, Miao-Li (TW)

Correspondence Address: WEI TE CHUNG;FOXCONN INTERNATIONAL, INC., 1650 MEMOREX DRIVE, SANTA CLARA, CA, 95050, US

(73) Assignees: INNOCOM TECHNOLOGY (SHENZHEN) CO., LTD.; INNOLUX DISPLAY CORP.

(21) Appl. No.: 11/903,865

(22) Filed: Sep. 24, 2007

(30) Foreign Application Priority Data
Sep. 22, 2007 (TW) 95135192

(51) Int. Cl. G02F 1/136; G01R 31/00

(52) U.S. Cl. 349/46; 324/770

(57) ABSTRACT

An integrated circuit for a liquid crystal panel (20) includes a booster circuit (221), which has a plurality of output terminals (225); a control circuit (222); a register (223); and a plurality of switchers (224). Each switch has a control terminal (2241) being connected to the register, a first terminal (2242) being connected to the output terminal of the booster circuit, and a second terminal (2243) being connected to the control circuit.

### FIELD OF THE INVENTION

The present invention relates to an integrated circuit, a liquid crystal panel with same and method for testing the integrated circuit.

### GENERAL BACKGROUND

FIG. 4 shows a conventional liquid crystal panel 10. The liquid crystal panel 10 has a display region 11 and a circuit region 12. A plurality of integrated circuit 120 is disposed on the circuit region 12, which is used to drive the display region 11 of the liquid crystal panel 10 to display images.

FIG. 5 shows an abbreviated diagram of the integrated circuit 120. The integrated circuit 120 includes a booster circuit 121 and a control circuit 122. The booster circuit 121 has a plurality of output ends 125, each of which is connected to the control circuit 122.

FIG. 6 is an abbreviated diagram showing a testing system 13 for testing the integrated circuit 120. The testing system 13 has a printed circuit board (PCB) 130 and an external power 140. The PCB 130 and the integrated circuit 120 are respectively connected to the booster circuit 121.

The external power 140 includes a directly current (DC) power 141 and a filtering capacitance 142. The filtering capacitance 142 is connected to two ends of the DC power 141 for filtering the noise signal of the output voltage from the DC power 141.

When the integrated circuit 120 operates, the PCB 130 outputs an enable signal to the booster circuit 121, and thus the output ends 125 respectively output a plurality of higher DC voltage to the control circuit 122.

When the integrated circuit 120 is tested, the external power 140 is connected to one test-needed output end 125, and provides a testing voltage to the control circuit 122 for testing if the integrated circuit 120 can work normally.

In the process of testing the integrated circuit 120, the booster circuit 121 and the control circuit 122 electrically connect in the process of testing the integrated circuit 120, i.e. the booster circuit 121 continues to output DC voltage to the control circuit 122. However, one output end 125 of the booster circuit 121 is connected to the external power 140, which is easy to output an overload voltage to burn out the control circuit 122. Thus, the integrated circuit 120 has a lower reliability in the testing process.

It is, therefore, desired to provide a power supply switching circuit and a flat panel display employing the power supply switching circuit that can overcome the above-described deficiencies.

### SUMMARY

In one aspect, an integrated circuit for a liquid crystal panel includes a booster circuit, which has a plurality of output terminals; a control circuit; a register; and a plurality of switchers. Each switch has a control terminal being connected to the register, a first terminal being connected to the output terminal of the booster circuit, and a second terminal being connected to the control circuit.

In another aspect, a liquid crystal display panel has a display region, and a circuit region. The circuit region has a plurality of integrated circuit for driving the display region. The integrated circuit includes a booster circuit, which has a plurality of output terminals; a control circuit; a register; and a plurality of switchers. Each switch has a control terminal being connected to the register, a first terminal being connected to the output terminal of the booster circuit, and a second terminal being connected to the control circuit.

In a further another aspect, a method for testing an integrated circuit for a liquid crystal panel, has the following steps: providing a turn-off signal to the switcher corresponding to the test-needed output terminal of the booster circuit through the register; cutting the electrical connection between the test-needed output terminal and the control circuit; and providing a test voltage to the control circuit.

Other novel features and advantages of the above-described power supply switching circuit and flat panel display will become more apparent from the following detailed description when taken in conjunction with the accompanying drawings.

### BRIEF DESCRIPTION OF THE DRAWINGS

FIG. 1 is a schematic plan view of a liquid crystal panel according to a preferred embodiment of the present invention, which includes a plurality of integrated circuits.

FIG. 2 is an abbreviated circuitry diagram of the integrated circuit of FIG. 1.

FIG. 3 is an abbreviated circuitry diagram of a testing system for testing the integrated circuit of FIG. 2.

FIG. 4 is a schematic plan view of a conventional liquid crystal panel according, which includes a plurality of integrated circuits.

FIG. 5 is an abbreviated circuitry diagram of the integrated circuit of FIG. 4.

FIG. 6 is an abbreviated circuitry diagram of a testing system, which is used to test the integrated circuit of FIG. 2.

### DETAILED DESCRIPTION OF PREFERRED EMBODIMENTS

Reference will now be made to the drawings to describe preferred and exemplary embodiments of the present invention in detail.

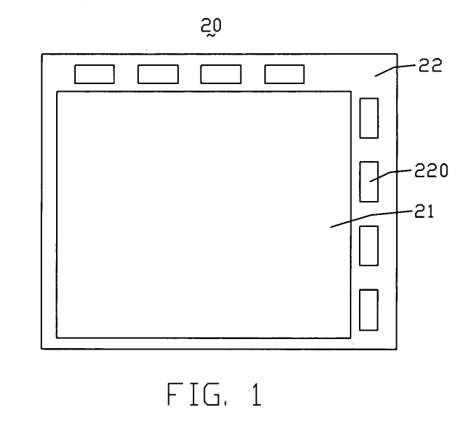

Referring to FIG. 1, a liquid crystal panel 20 according to a preferred embodiment of the present invention is shown. The liquid crystal panel 20 includes a display region 21 and a circuit region 22. The circuit region 22 has a plurality of integrated circuits 220 disposed thereon, which are used to drive the display region 21 to display images.

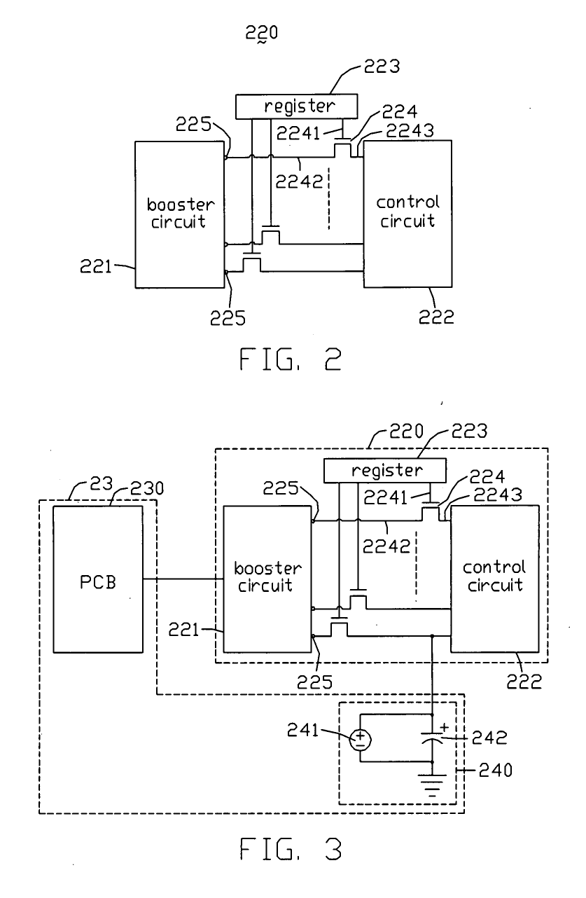

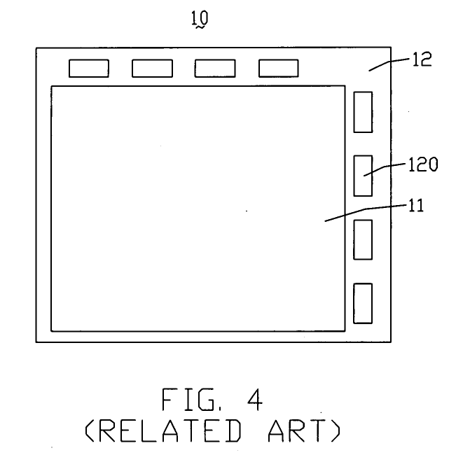

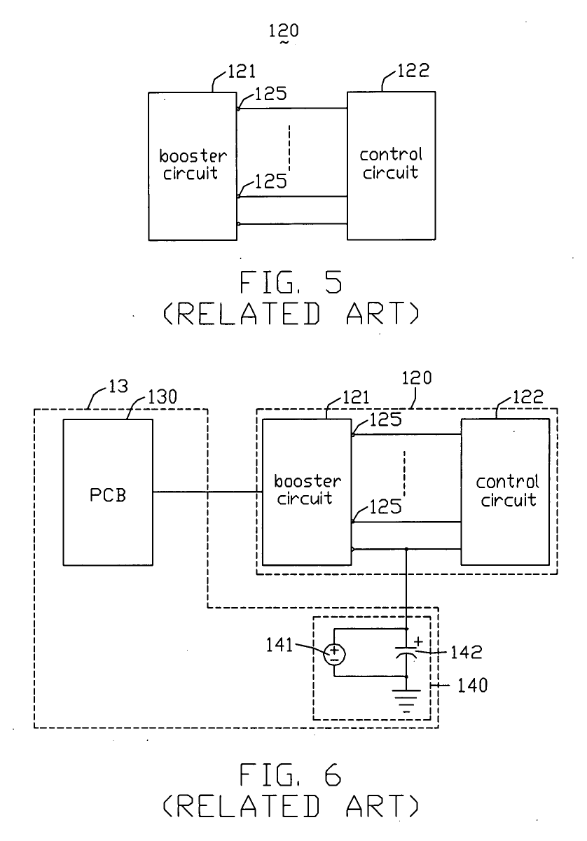

Further referring to FIG. 2, an abbreviated circuitry diagram of the integrated circuit 220 is shown. The integrated circuit 220 has a booster circuit 221, a plurality of transistors 224, a control circuit 222 and a register 223. The booster circuit 221 includes a plurality of output terminals 225. Each transistor 224 is N-Channel Metal-Oxide-Semiconductor Field-Effect Transistor (N-MOSFET), which has a gate electrode 2241 connected to the register 223, a source electrode 2242 connected to one output terminal 225, and a drain electrode 2243 connected to the control circuit 222.

FIG. 3 shows a testing system 23 for testing the integrated circuit 220. The testing system 23 includes a printed circuit board (PCB) 230 and an external power 240, which the PCB 230 and the external power 240 are respectively connected to booster circuit 221.

The external power 240 includes a direct current (DC) power 241 and a filtering capacitance 242. The filtering capacitance 242 is connected to two ends of the DC power 241 for filtering the noise signal of the output voltage from the DC power 241.

When the integrated circuit 220 normally works, the output circuit 230 outputs an enable signal to the booster circuit 221, and the register 223 provides a plurality of start signal to the plurality of transistors 224 for turning on each transistor 224, under a control signal. Thus, the plurality of output terminals 225 of the booster circuit 221 respectively output a plurality of higher DC voltage to the control circuit 222.

When the integrated circuit 220 is tested, the external power 240 is connected to one test-needed output terminal 225 of the booster circuit 221. The register 223 provides a tlrn-off signal, under a control order, to the gate electrode 2241 of the transistor 224 connected to the test-needed output terminal 225, for cutting the electrical connection between the test-needed output terminal 225 and the control circuit 222. The external power 240 provides a test signal to the control circuit 222 through the drain electrode 2243 of one transistor 224 for testing if the integrated circuit 220 works normally.

In the testing process, the register 223 can turn off the corresponding transistors 224 to cut the electrical connection between the test-needed output terminal 225 and the control circuit 222. Thus, the integrated circuit 220 can be avoided to be burned out in the process of being tested. Therefore, the integrated circuit 220 has a higher reliability.

In addition, the integrated circuit 220 can have various alternative modifications. The transistor 224 can be other switching elements having a control terminal, a first terminal and a second terminal, the control terminal being connected to the register 223, the first terminal being connected to the output terminal 225, the second terminal being connected to the control circuit 222. The control terminal can control the turn-on or turn-off of the first and the second terminals. The transistor 224 also can be a P-channel metal-oxide-semiconductor field-effect transistor (P-MOSFET). Moreover, the transistor 224 can be a semiconductor triode, such as bipolar NPN semiconductor triode or bipolar PNP semiconductor triode, which has a base electrode being connected to the register, an emitter electrode being connected to the output terminal 225, and a connector electrode being connected to the control circuit 222.

It is to be understood, however, that even though numerous characteristics and advantages of preferred and exemplary embodiments have been set out in the foregoing description, together with details of the structures and functions of the embodiments, the disclosure is illustrative only; and that changes may be made in detail within the principles of present invention to the full extent indicated by the broad general meaning of the terms in which the appended claims are expressed.

What is claimed is:

1. An integrated circuit for a liquid crystal panel, comprising:
a booster circuit comprising a plurality of output terminals;
a control circuit;
a register; and
a plurality of switchers comprising a control terminal being connected to the register, a first terminal being connected to the output terminal of the booster circuit, and a second terminal being connected to the control circuit.

2. The integrated circuit as claimed in claim 1, wherein the switcher is a transistor, the control terminal is a gate electrode, the first terminal is a source electrode, and the second terminal is a drain electrode.

3. The integrated circuit as claimed in claim 2, wherein the transistor is n-channel metal-oxide-semiconductor field-effect transistor (N-MOSFET).

4. The integrated circuit as claimed in claim 2, wherein the transistor is p-channel metal-oxide-semiconductor field-effect transistor (P-MOSFET).

5. The integrated circuit as claimed in claim 1, wherein the switcher is a semiconductor triode, the control terminal is a base electrode, the first terminal is an emitter electrode, and the second terminal is a connector electrode.

6. The integrated circuit as claimed in claim 5, wherein the semiconductor triode is bipolar NPN semiconductor triode.

7. The integrated circuit as claimed in claim 5, wherein the semiconductor triode is bipolar PNP semiconductor triode.

8. A liquid crystal display panel, comprising:
a display region, and
a circuit region comprising a plurality of integrated circuit for driving the display region, the integrated circuit comprising:
a booster circuit comprising a plurality of output terminals;
a control circuit;
a register; and
a plurality of switchers comprising a control terminal being connected to the register, a first terminal being connected to the output terminal of the booster circuit, and a second terminal being connected to the control circuit.

9. The liquid crystal display panel as claimed in claim 8, wherein the switcher is a transistor, the control terminal is a gate electrode, the first terminal is a source electrode, and the second terminal is a drain electrode.

10. The liquid crystal display panel as claimed in claim 9, wherein the transistor is n-channel metal-oxide-semiconductor field-effect transistor (N-MOSFET).

11. The liquid crystal display panel as claimed in claim 9, wherein the transistor is p-channel metal-oxide-semiconductor field-effect transistor (P-MOSFET).

12. The liquid crystal display panel as claimed in claim 8, wherein the switcher is a semiconductor triode, the control terminal is a base electrode, the first terminal is an emitter electrode, and the second terminal is a connector electrode.

13. The liquid crystal display panel as claimed in claim 12, wherein the semiconductor triode is bipolar NPN semiconductor triode.

14. The liquid crystal display panel as claimed in claim 12, wherein the semiconductor triode is bipolar PNP semiconductor triode.

15. A method for testing the integrated circuit for a liquid crystal panel as claimed in claim 1, comprising:
providing a turn-off signal to the switcher corresponding to the test-needed output terminal of the booster circuit through the register;
cutting the electrical connection between the test-needed output terminal and the control circuit; and
providing a test voltage to the control circuit.
